(19) United States
(12) Patent Application Publication
(10) Pub. No.: US 2013/0106468 A1
(43) Pub. Date: May 2, 2013

(54) GATE DRIVER

(71) Applicant: Sanken Electric Co., Ltd., Niiza-shi (JP)

(72) Inventor: Shinji ASO, Niiza-shi (JP)

(73) Assignee: Sanken Electric Co., Ltd., Niiza-shi (JP)

(21) Appl. No.: 13/659,091

(22) Filed: Oct. 24, 2012

(30) Foreign Application Priority Data
Nov. 1, 2011 (JP) 2011-239938

(51) Int. Cl. H03K 3/00

(52) U.S. Cl. 327/109

(57) ABSTRACT

A gate driver for driving a switching element Q1 that is able to be bidirectionally conductive includes a drive part 2 that applies a positive voltage to a gate of the switching element to turn on the switching element and a negative voltage to the gate to turn off the switching element and a negative voltage release part 3 that, before a reverse current is passed to the switching element, releases the negative voltage from being applied to the gate of the switching element.

### BACKGROUND OF THE INVENTION

1. Field of the Invention

The present invention relates to a gate driver for driving a gate of a switching element that is able to be bidirectionally conductive.

2. Description of Related Art

An example of a gate driver for driving a gate-driven semiconductor element having a conductivity modulation effect is disclosed in Japanese Unexamined Patent Application Publication No. 2010-51165 (Patent Literature 1). According to this related art, the gate driver includes a capacitor and a resistor that are connected in parallel. The gate driver is inserted between a switching output circuit and a gate of the gate-driven semiconductor element. The capacitor of the gate driver and a gate input capacitance of the gate-driven semiconductor element perform voltage division to apply a voltage over an ON threshold voltage of the gate-driven semiconductor element to the gate of the gate-driven semiconductor element, thereby turning on the gate-driven semiconductor element at high speed and supplying a current for sustaining a conductivity modulation through the resistor of the gate driver to the gate of the gate-driven semiconductor element.

The related art actively uses the gate capacitance of the gate-driven semiconductor element, to reduce the number of parts, simplify a circuit configuration, improve an operation speed, and minimize a loss.

If the gate-driven semiconductor element is used in circumstances to receive a return current, it must be provided with a freewheel diode between the main electrodes (for example, source and drain) thereof, to minimize a loss caused by the return current. For example, an inductive load driven with a bridge circuit creates a return current, and if the bridge circuit employs a switching element having no body diode, the return current will pass through the switching element. To avoid the return current, the switching element must have a freewheel diode connected in parallel with the switching element.

### SUMMARY OF THE INVENTION

FIG. 1 illustrates the characteristics of a switching element that is able to be bidirectionally conductive. A reverse breakdown voltage of the switching element is dependent on a gate-source voltage Vgs thereof. If no freewheel diode is provided, the switching element passes a reverse current at a drain-source voltage Vds that is dependent on the gate-source voltage Vgs. Accordingly, the switching element having no freewheel diode causes a large loss represented by a relationship of (drain-source voltage Vds)×(drain-source current Ids). The freewheel diode has recovery characteristics to pass a recovery current when a reverse breakdown voltage is applied thereto. The recovery current tends to cause a loss and noise and this prevents the switching element from improving efficiency, minimizing noise, or reducing dimensions.

The present invention provides a gate driver for driving a switching element that is able to be bidirectionally conductive, capable of minimizing a loss even when a reverse current passes through the switching element.

According to an aspect of the present invention, the gate driver for driving a switching element that is able to be bidirectionally conductive includes a drive part applying a positive voltage to a gate of the switching element to turn on the switching element and a negative voltage to the gate to turn off the switching element and a negative voltage release part releasing the applying of the negative voltage to the gate of the switching element before causing a reverse current passing through the switching element.

### BRIEF DESCRIPTION OF THE DRAWINGS

FIG. 1 is a graph illustrating characteristics of a switching element that is able to be bidirectionally conductive and is driven with a gate driver according to a related art;

FIG. 2 is a circuit diagram illustrating a gate driver according to a related art;

FIG. 3 is a timing chart illustrating operation of the gate driver of FIG. 2;

FIG. 4 is a circuit diagram illustrating a gate driver according to Embodiment 1 of the present invention;

FIG. 5 is a timing chart illustrating operation of the gate driver of FIG. 4;

FIG. 6 is a circuit diagram illustrating a DC/DC converter employing a gate driver according to Embodiment 2 of the present invention;

FIG. 7 is a timing chart illustrating operation of the gate driver of FIG. 6;

FIG. 8 is a circuit diagram illustrating a gate driver according to Embodiment 3 of the present invention;

FIG. 9 is a timing chart illustrating operation of the gate driver of FIG. 8;

FIG. 10 is a circuit diagram illustrating a DC/DC converter employing a gate driver according to Embodiment 4 of the present invention;

FIG. 11 is a timing chart illustrating operation of the gate driver of FIG. 10;

FIG. 12 is a circuit diagram illustrating a gate driver according to Embodiment 5 of the present invention; and

FIG. 13 is a circuit diagram illustrating a gate driver according to Embodiment 6 of the present invention.

### DESCRIPTION OF PREFERRED EMBODIMENTS

Gate drivers according to embodiments of the present invention will be explained in detail with reference to the drawings.

### Embodiment 1

A gate driver according to Embodiment 1 of the present invention applies a positive voltage to a gate of a switching element that is able to be bidirectionally conductive to turn on the switching element, applies a negative voltage to the gate to turn off the switching element, and before a reverse current passes through the switching element, releases the applying of the negative voltage to the gate of the switching element.

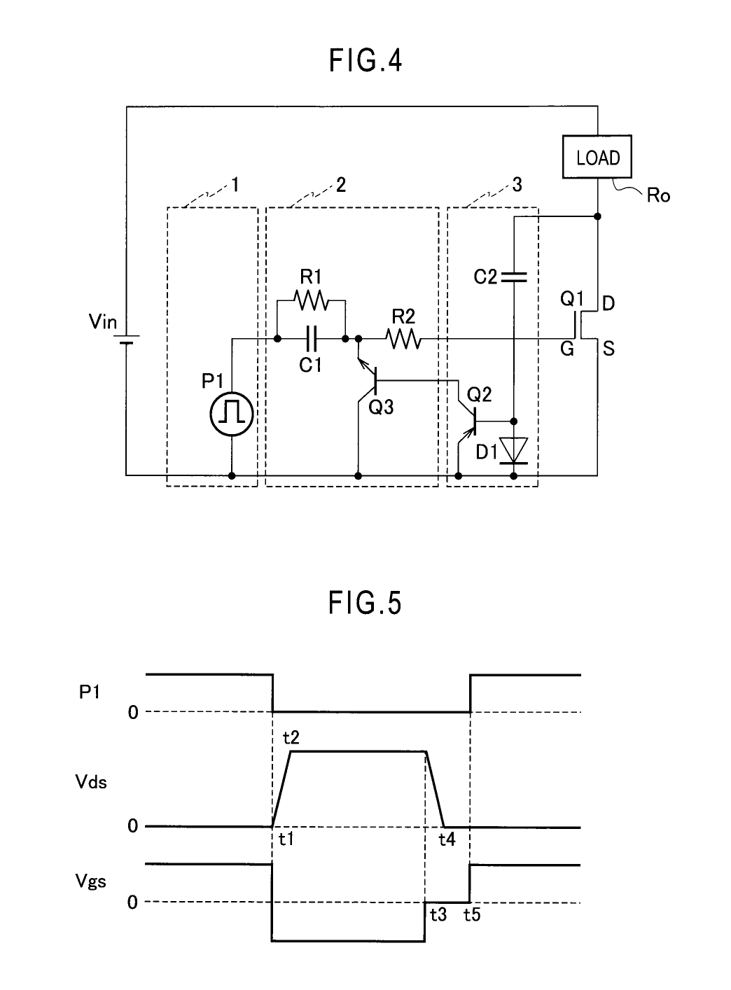

FIG. 4 is a circuit diagram illustrating the gate driver according to Embodiment 1. The gate driver includes a switching element Q1, a control part 1, a drive part 2, and a change detector 3. Both ends of a DC power source Vin are connected to a series circuit including a load Ro and the switching element Q1.

The switching element Q1 is a gate-driven semiconductor element such as a gallium nitride field effect transistor (GaNFET) that is able to be bidirectionally conductive.

The control part 1 has a pulse generator P1. The pulse generator P1 generates a pulse signal to control ON/OFF of the switching element Q1 and sends the pulse signal to the drive part 2.

The change detector 3 corresponds to the “negative voltage release part” stipulated in the claims. The change detector 3 detects a temporal change dV/dt in a drain-source voltage Vds of the switching element Q1 by way of a differential circuit including the capacitor C2, and according to the detected change dV/dt, provides the drive part 2 with a release signal to release the applying of the negative voltage to the gate of the switching element Q1 before a reverse current passing through the switching element Q1. The temporal change of the drain-source voltage Vds is represented by dV/dt in a time derivative sense. The change detector 3 releases the negative voltage from being applied to the gate of the switching element Q1 when the detected dV/dt becomes negative.

The change detector 3 has a capacitor C2, a diode D1, and a pnp transistor Q2. A first end of the capacitor C2 is connected to a drain of the switching element Q1 and a second end of the capacitor C2 is connected to an anode of the diode D1 and a base of the transistor Q2. A cathode of the diode D1, an emitter of the transistor Q2, and a source of the switching element Q1 are connected to a negative electrode of the DC power source Vin. A collector of the transistor Q2 is connected to a base of an npn transistor Q3 of the drive part 2.

According to the pulse signal from the pulse generator P1, the drive part 2 applies the positive voltage to the gate of the switching element Q1 to turn on the switching element Q1 and the negative voltage to the gate of the switching element Q1 to turn off the switching element Q1. According to the release signal of the change detector 3, the drive part 2 releases applying of the negative voltage to the gate of the switching element Q1 before causing of a reverse current passing through the switching element Q1.

The drive part 2 has a resistor R1, a capacitor C1, a resistor R2, and the transistor Q3. The resistors R1 and R2 form a series circuit arranged between the control part 1 and the gate G of the switching element Q1. The resistor R1 and capacitor C1 are connected in parallel with each other.

An emitter of the transistor Q3 is connected to a connection point of the resistors R1 and R2, a collector of the transistor Q3 is connected to the negative electrode of the DC power source Vin, and the base of the transistor Q3 is connected to the collector of the transistor Q2.

Operation of the gate driver according to Embodiment 1 will be explained with reference to the timing chart of FIG. 5.

In FIG. 5, P1 is the pulse signal generated by the pulse generator P1, Vds is the drain-source voltage of the switching element Q1, and Vgs is a gate-source voltage of the switching element Q1. The switching element Q1 has a low gate threshold voltage, and therefore, a negative voltage is applied to the gate of the switching element Q1 during an OFF period of the switching element Q1.

Before t1, the pulse signal P1 is positive and is applied to the gate of the switching element Q1 to turn on the switching element Q1.

At t1, the voltage of the pulse signal P1 becomes zero. A first end of the capacitor C1 on the pulse generator P1 side becomes a positive voltage and a second end of the capacitor C1 on the gate side of the switching element Q1 becomes a negative voltage. As a result, the gate-source voltage Vgs of the switching element Q1 becomes negative. The switching element Q1, therefore, turns off during a period from t1 to t3. In a period from t1 to t2, the drain-source voltage Vds of the switching element Q1 increases, and in a period from t2 to t3, maintains a constant value.

At t3, the drain-source voltage Vds of the switching element Q1 decreases and a current clockwise passes through a path extending along the emitter of Q2, the base of Q2, C2, the drain of Q1, and the source of Q1, to decrease the voltage of the capacitor C2. According to the temporal change in the voltage of the capacitor C2, a change dV/dt in the drain-source voltage Vds of the switching element Q1 is detected.

When the transistor Q2 turns on, a current passing through the emitter of Q2, the collector of Q2, and the base of Q3 causes a current counterclockwise passing through a path extending along the emitter of Q3, C1, P1, and the collector of Q3. As a result, the capacitor C1 discharges to zero voltage during a period from t3 to t5.

Namely, the negative voltage of the capacitor C1 is released at t3 when the voltage change dV/dt in the drain-source voltage Vds of the switching element Q1 becomes negative, thereby stopping the negative voltage from being applied to the gate of the switching element Q1.

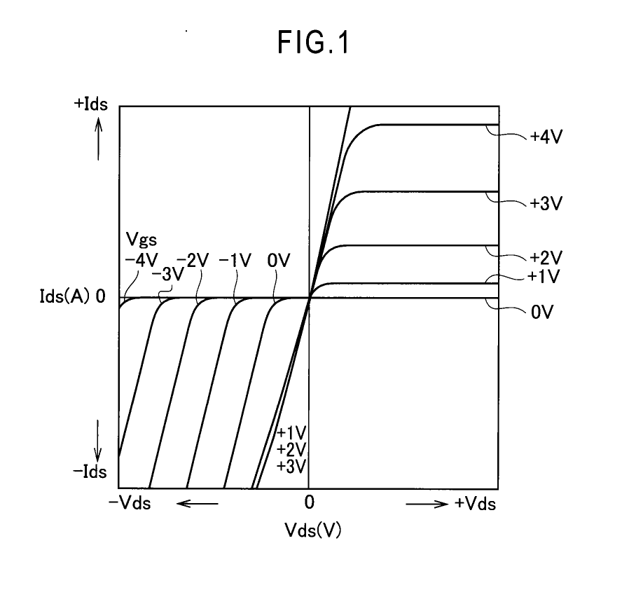

At this time, the drain-source voltage Vds of the switching element Q1 will follow a segment of “Vgs=0 V” illustrated in the third quadrant of FIG. 1. Even if a regenerative current (not illustrated) passes between the source and drain of the switching element Q1 in a period from t4 to t5, the drain-source voltage Vds is small to reduce a loss of the switching element Q1.

In this way, the gate driver according to Embodiment 1 utilizes the characteristics illustrated in FIG. 1 of the switching element Q1, to release applying of a negative voltage to the gate G of the switching element Q1 before causing a reverse current passing through the switching element Q1.

This minimizes a loss of the switching element Q1 even when a reverse current passes through the switching element Q1.

Embodiment 1 realizes high efficiency without connecting a freewheel diode in parallel with the switching element Q1. Since Embodiment 1 employs no freewheel diode, it minimizes noise and dimensions.

### Embodiment 2

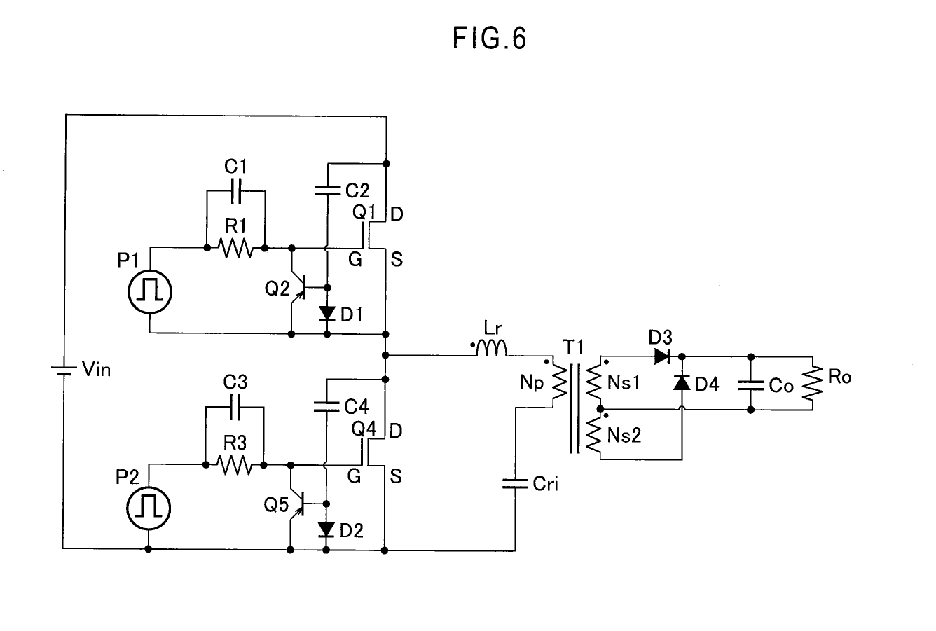

FIG. 6 is a circuit diagram illustrating a DC/DC converter employing a gate driver according to Embodiment 2 of the present invention. In FIG. 6, both ends of a DC power source Vin are connected to a series circuit including switching elements Q1 and Q4. The switching elements Q1 and Q4 are gate-driven semiconductor elements such as GaNFETs that are able to be bidirectionally conductive.

A first gate driver includes the switching element Q1, a pulse generator P1, a resistor R1, a capacitor C1, a diode D1, a capacitor C2, and a transistor Q2. Compared with the gate driver of Embodiment 1 of FIG. 4, the first gate driver of Embodiment 2 is not provided with the transistor Q3 and resistor R2. A second gate driver includes the switching element Q4, a pulse generator P2, a resistor R3, a capacitor C3, a diode D2, a capacitor C4, and a transistor Q5. Compared with the gate driver of Embodiment 1 of FIG. 4, the second gate driver of Embodiment 2 is not provided with the transistor Q3 and resistor R2. The first and second gate drivers according to Embodiment 2 each are similar to the gate driver of Embodiment 1, operate like the gate driver of Embodiment 1, and provide effects similar to those provided by the gate driver of Embodiment 1.

Connected between drain and source of the switching element Q4 is a series circuit including a reactor Lr, a primary winding Np of a transformer T1, and a current resonance capacitor Cri. A first end of a first secondary winding Ns1 of the transformer T1 is connected to an anode of a diode D3 and a second end of the first secondary winding Ns1 is connected to a first end of a second secondary winding Ns2 of the transformer T1. A second end of the second secondary winding Ns2 is connected to an anode of a diode D4. Cathodes of the diodes D3 and D4 are connected to a first end of a capacitor Co and a first end of a load Ro. A second end of the capacitor Co and a second end of the load Ro are connected to a connection point of the first and second secondary windings Ns1 and Ns2.

Frequencies of pulse signals generated by the pulse generators P1 and P2 are controlled according to a voltage across the capacitor Co.

Operation of the DC/DC converter of FIG. 6 will be explained. When the switching element Q1 turns on and the switching element Q2 off, a current clockwise passes through a path extending along a positive electrode of Vin, Q1, Lr, Np, Cri, and a negative electrode of Vin. On the secondary side of the transformer T1, a current clockwise passes through a path extending along Ns1, D3, Co, and Ns1.

When the switching element Q1 turns off with the switching element Q2 being OFF, a current clockwise passes through a path extending along Cri, Q4, Lr, Np, and Cri. When the switching element Q1 is OFF and the switching element Q2 turns on, a current counterclockwise passes through a path extending along Cri, Np, Lr, Q4, and Cri. On the secondary side of the transformer T1, a current passes through a path extending along Ns2, D4, Co, and Ns2.

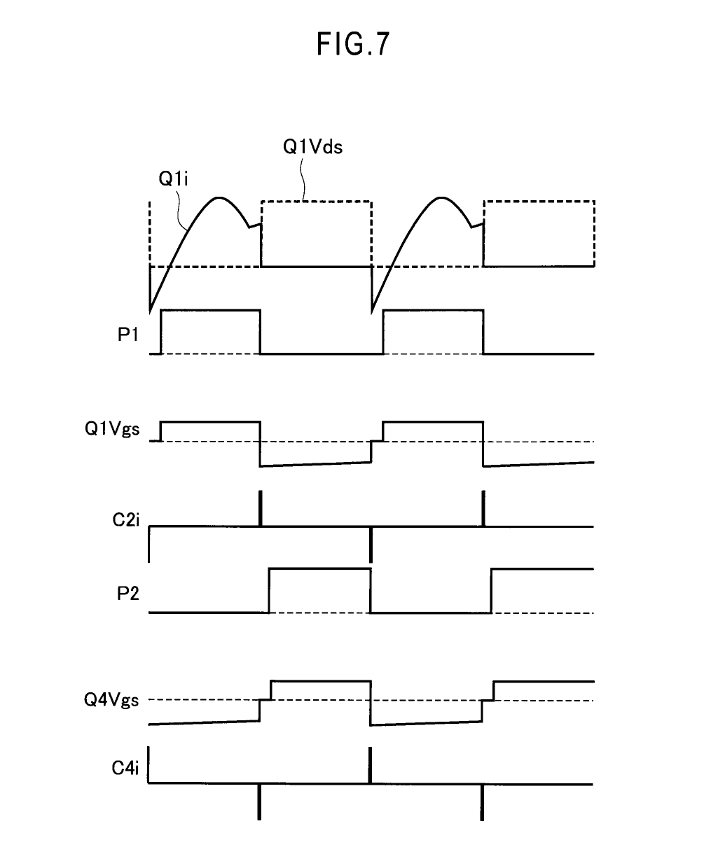

FIG. 7 is a timing chart illustrating operation of the gate driver according to the present embodiment. In FIG. 7, Q1i is a drain current of the switching element Q1, Q1Vds is a drain-source voltage of the switching element Q1, P1 is the pulse signal generated by the pulse generator P1, Q1Vgs is a gate-source voltage of the switching element Q1, C2i is a current passing through the capacitor C2, P2 is the pulse signal generated by the pulse signal generator P2, Q4Vgs is a gate-source voltage of the switching element Q4, and C4i is a current passing through the capacitor C4.

Embodiment 2 provides effects similar to those provided by Embodiment 1.

### Embodiment 3

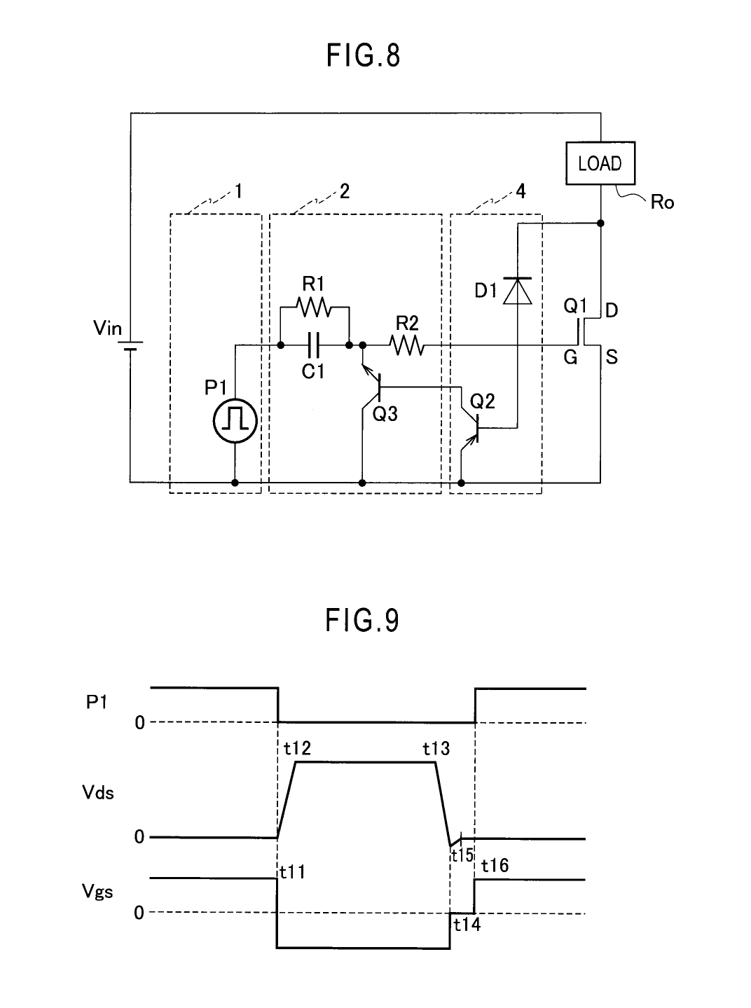

FIG. 8 is a circuit diagram illustrating a gate driver according to Embodiment 3 of the present invention. The gate driver according to Embodiment 3 employs a voltage detector 4 instead of the change detector 3 of the gate driver according to Embodiment 1 illustrated in FIG. 4. The remaining configuration of FIG. 8 is the same as that of FIG. 4, and therefore, only the voltage detector 4 will be explained.

The voltage detector 4 corresponds to the “negative voltage release part” stipulated in the claims. The voltage detector 4 detects a drain voltage of a switching element Q1, and if the detected drain voltage becomes negative, provides a drive part 2 with a release signal to release a negative voltage from being applied to a gate of the switching element Q1. According to the release signal of the voltage detector 4, the drive part 2 releases applying of a negative voltage to the gate of the switching element Q1.

The voltage detector 4 includes a diode D1 and a transistor Q2. A cathode of the diode D1 is connected to a drain of the switching element Q1 and an anode of the diode D1 is connected to a base of the transistor Q2. Connection between the transistor Q2 and a transistor Q3 is the same as that of FIG. 4.

FIG. 9 is a timing chart illustrating operation of the gate driver according to Embodiment 3. In FIG. 9, operation in a period from t11 to t13 is the same as that in the period from t1 to t3 of FIG. 5, and therefore, will not be explained.

At t14 in FIG. 9, a drain-source voltage Vds of the switching element Q1 becomes negative and a current clockwise passes through a path extending along an emitter of Q2, the base of Q2, D1, the drain of Q1, and a source of Q1. Namely, the negative drain-source voltage Vds of the switching element Q1 is detected according to a forward voltage of the diode D1.

When the transistor Q2 turns on, a current passing through the emitter of Q2, a collector of Q2, and a base of Q3 causes a current passing through a path extending along an emitter of Q3, C1, P1, and a collector of Q3. This results in discharging the capacitor C1 and the voltage of the capacitor C1 becomes zero in a period from t13 to t16. At this time, the diode D1 and transistor Q2 are ON to short-circuit the gate and source of the switching element Q1. As a result, the drain-source voltage Vds of the switching element Q1 in a period from t14 to t15 demonstrates the characteristics represented by the curve of “Vgs=0V” as depicted in FIG. 1.

In this way, Embodiment 3 cancels the negative voltage of the capacitor C1 when the drain-source voltage Vds of the switching element Q1 becomes negative, thereby releasing applying of the negative voltage to the gate of the switching element Q1. Embodiment 3 provides effects similar to those provided by Embodiment 1.

### Embodiment 4

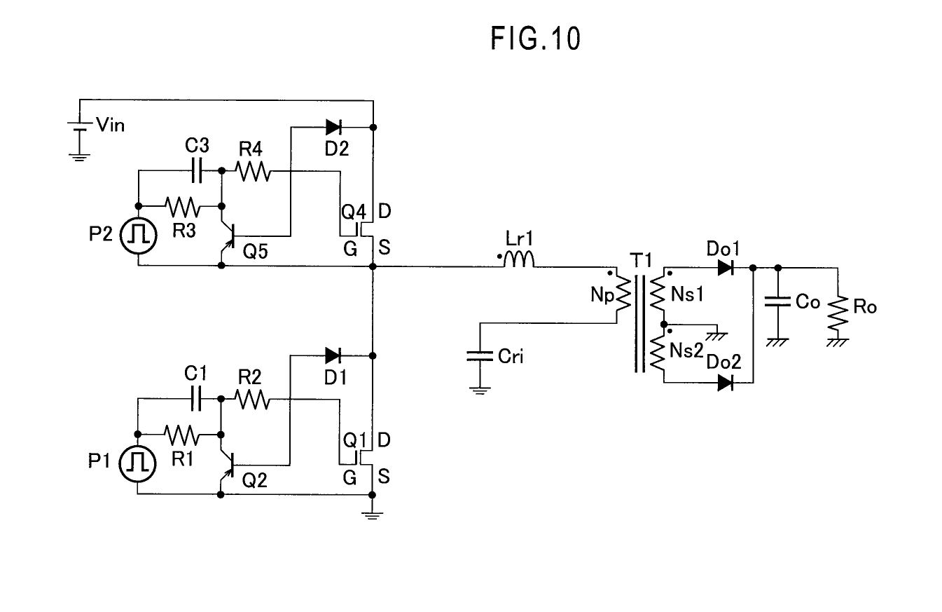

FIG. 10 is a circuit diagram illustrating a DC/DC converter employing a gate driver according to Embodiment 4 of the present invention. In FIG. 10, a first gate driver includes a switching element Q1, a pulse generator P1, a resistor R1, a capacitor C1, a diode D1, and a transistor Q2. Compared with the gate driver of Embodiment 3 of FIG. 8, the first gate driver of Embodiment 4 is not provided with the transistor Q3. A second gate driver includes a switching element Q4, a pulse generator P2, a resistor R3, a capacitor C3, a diode D2, and a transistor Q5. Compared with the gate driver of Embodiment 3 of FIG. 8, the second gate driver of Embodiment 4 is not provided with the transistor Q3. The first and second gate drivers according to Embodiment 4 each are similar to the gate driver of Embodiment 3, operate like the gate driver of Embodiment 3, and provide effects similar to those provided by the gate driver of Embodiment 3.

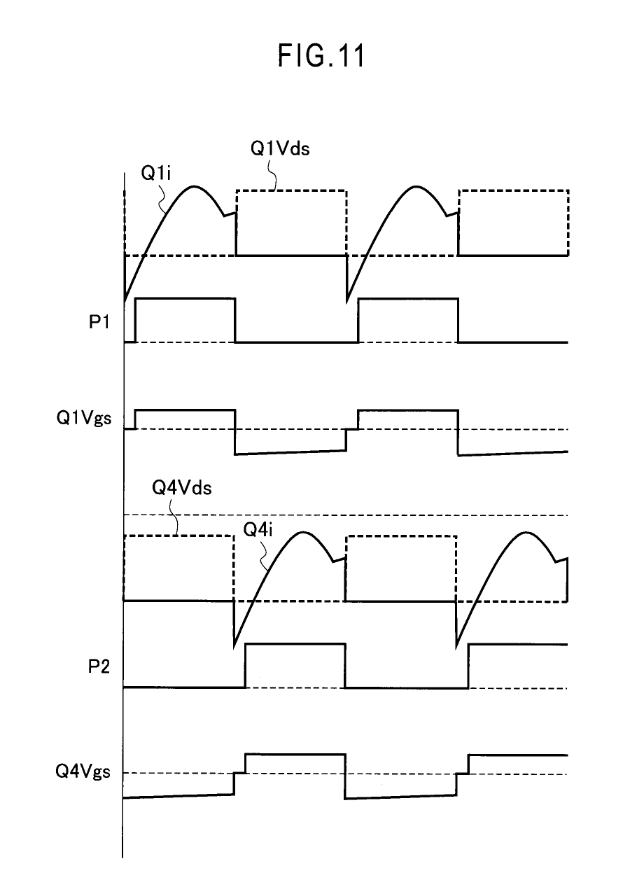

The remaining configuration and operation of FIG. 10 are the same as those of FIG. 6, and therefore, explanations thereof are omitted. FIG. 11 is a timing chart illustrating operation of the gate driver according to Embodiment 4. In FIG. 11, Q4i is a drain current of the switching element Q4, Q4Vds is a drain-source voltage of the switching element Q4, and Q4Vgs is a gate-source voltage of the switching element Q4.

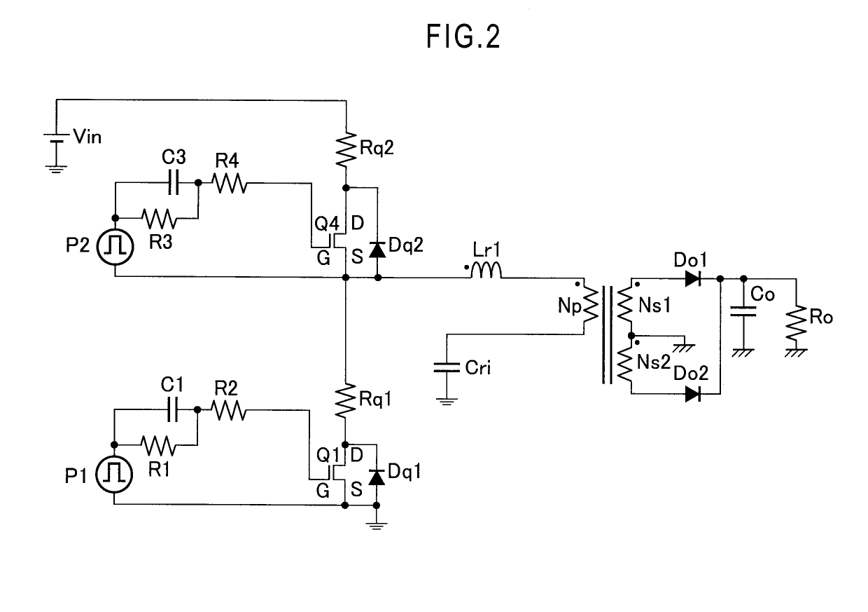

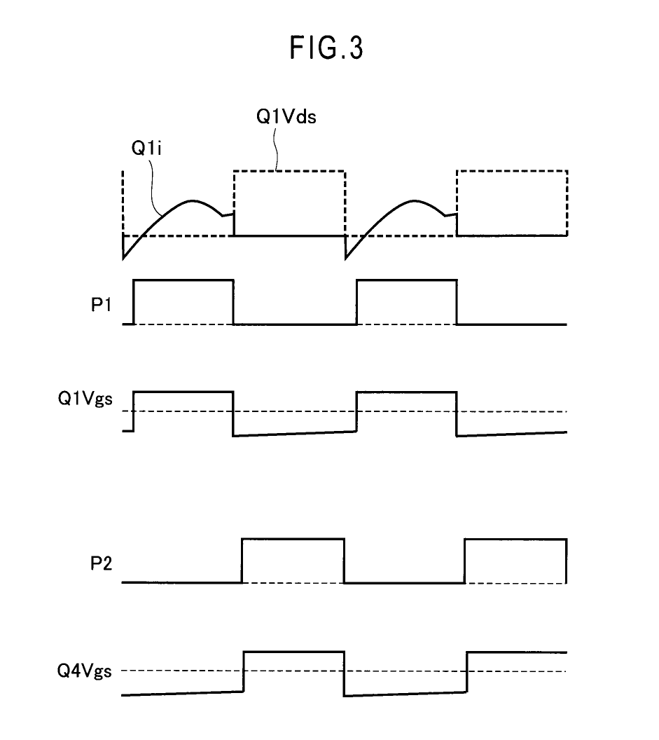

In connection with Embodiment 4, FIG. 2 illustrates a circuit diagram of a gate driver according to a related art and FIG. 3 illustrates a timing chart of the gate driver according to the related art.

### Embodiment 5

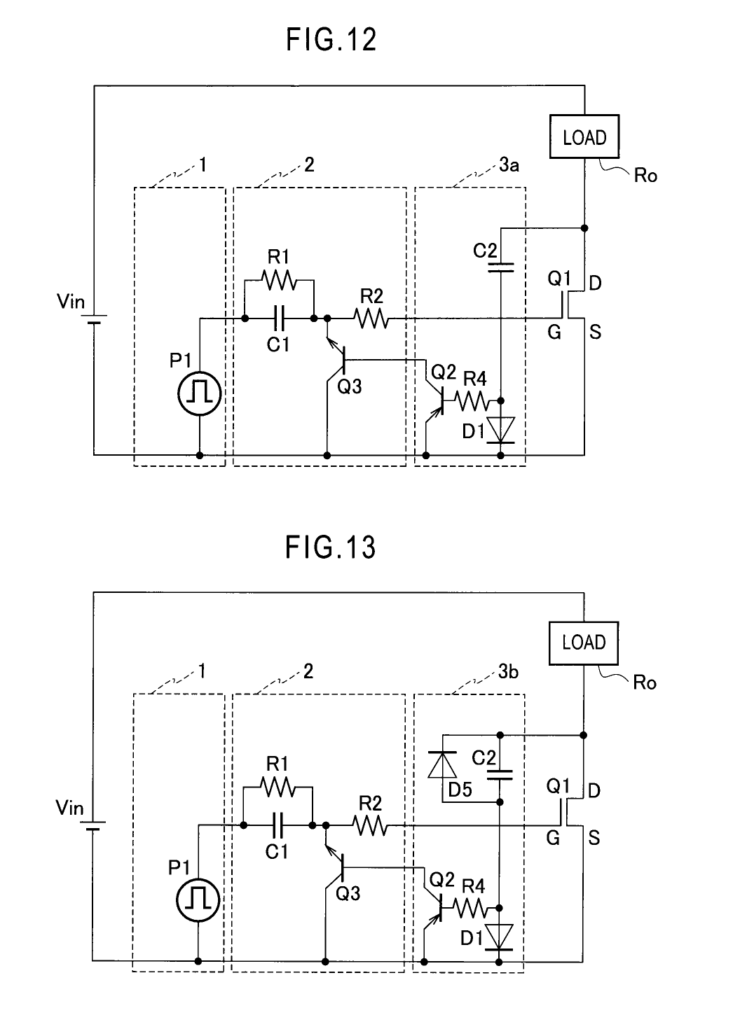

FIG. 12 is a circuit diagram illustrating a gate driver according to Embodiment 5 of the present invention. Compared with the gate driver according to Embodiment 1 of FIG. 4, the gate driver according to Embodiment 5 employs a change detector 3a that additionally includes a base resistor R4 connected between a base of a transistor Q2 and an anode of a diode D1.

With the base resistor R4, a capacitor C2 discharges according to a time constant determined by the resistor R4 and capacitor C2, to extend a detection time of “dV/dt” detected by the change detector 3a.

### Embodiment 6

FIG. 13 is a circuit diagram illustrating a gate driver according to Embodiment 6 of the present invention. Compared with the gate driver according to Embodiment 5 of FIG. 12, the gate driver according to Embodiment 6 employs a change detector 3b that additionally includes a diode D5 connected in parallel with a capacitor C2.

With the capacitor C2 and diode D5, the gate driver according to Embodiment 6 detects “dV/dt” through the capacitor C2 followed by a voltage detection of the diode D5. Accordingly, Embodiment 6 surely detects when a drain voltage of a switching element Q1 becomes negative. The capacitor C2 may be replaced with a pn junction capacitance of the diode D5.

The present invention is not limited to the gate drivers of Embodiments 1 to 6. For example, the capacitor arranged in the voltage detector 3 may be replaced with a junction capacitance of the diode that is also arranged in the voltage detector 3.

In FIG. 9 that illustrates operation of the gate driver of Embodiment 3, the drain-source voltage Vds of the switching element Q1 changes from positive to negative in the period from t13 to t14. At this time, a threshold voltage Vth of the switching element Q1 may be set between zero and a maximum value of the drain-source voltage Vds so that, when the drain-source voltage Vds becomes lower than the threshold voltage Vth, the negative voltage to the gate of the switching element Q1 is removed.

In each of the embodiments, the switching element is made of nitride semiconductor such as gallium nitride (GaN). Instead, the switching element may be made of wide-bandgap semiconductor such as silicon carbide or diamond.

According to the present invention, the negative voltage release part releases applying of a negative voltage to the gate of the switching element before causing a reverse current passing through the switching element. Accordingly, the present invention is capable of improving the efficiency of the switching element without using a freewheel diode. Since the present invention needs no freewheel diode, the gate driver according to the present invention minimizes noise and dimensions.

The present invention is applicable to gate drivers for driving gates of switching elements that are able to be bidirectionally conductive.

This application claims benefit of priority under 35 USC §119 to Japanese Patent Application No. 2011-239938, filed on Nov. 1, 2011, the entire contents of which are incorporated by reference herein.

What is claimed is:

1. A gate driver for driving a switching element that is able to be bidirectionally conductive, comprising:
a drive part configured to apply a positive voltage to a gate of the switching element to turn on the switching element and a negative voltage to the gate to turn off the switching element; and
a negative voltage release part configured to release applying of the negative voltage to the gate of the switching element before causing a reverse current passing through the switching element.

2. The gate driver of claim 1, wherein
the negative voltage release part includes a change detector configured to detect a temporal change in a drain-source voltage of the switching element; and
when the detected temporal change becomes negative, the negative voltage release part releases the applying of the negative voltage to the gate of the switching element.

3. The gate driver of claim 1, wherein the negative voltage release part includes a voltage detector that detects a drain voltage of the switching element; and
when the detected drain voltage becomes negative, the negative voltage release part releases the applying of the negative voltage to the gate of the switching element.

4. The gate driver of claim 1, wherein the switching element is a wide-bandgap semiconductor device.
